(19) United States
(12) Patent Application Publication
(10) Pub. No.: US 2020/0150777 A1
(43) Pub. Date: May 14, 2020

(54) MULTI-STEP MECHANICAL SWITCH FOR A KEYBOARD

(71) Applicant: Logitech Europe S.A., Lausanne (CH)

(72) Inventors: Feng-Hao Lin, Hsinchu City (TW); Nai Hsiang Mah, Hsinchu City (TW)

(73) Assignee: Logitech Europe S.A., Lausanne (CH)

(21) Appl. No.: 16/189,698

(22) Filed: Nov. 13, 2018

(51) Int. Cl. G06F 3/02; H01H 13/7073; H01H 13/86; H03K 17/967

(52) U.S. Cl. CPC G06F 3/0202; H01H 13/7073; H01H 2235/01; H03K 17/967; H01H 13/86

(57) ABSTRACT

This disclosure describes various configurations for a keyboard having multiple key assemblies. Each of the key assemblies includes a keycap and a key stem supporting the keycap that includes a protrusion extending laterally therefrom. A first biasing member supports the key stem and is configured to provide a linear feedback response during actuation of the key assembly. A second biasing member is configured to engage the protrusion during actuation of the key assembly. The second biasing member has a user-configurable feedback response. In some embodiments, the first biasing member can be a compression spring and the second biasing member can be a torsion spring.

### BACKGROUND

Keyboards have become a ubiquitous input control for conventional computing devices. The keyboards can take the form of standalone wired or wireless input controllers or be integrated with portable electronic devices such as laptop and tablet computing devices. While input feedback mechanisms vary, each key of a keyboard is generally designed to provide a user with positive confirmation that the key has been actuated. These input feedback mechanisms can vary substantially. For example, feedback mechanisms for basic low-profile keyboards might only include a dome switch or scissor mechanism for each key while more mechanical keyboards can include spring mechanisms that provide a certain amount of linear feedback prior to actuation. Unfortunately, given the large population of users it is hard to design a keyboard that is well-suited for a large cross-section of users.

For this reason, mechanisms for adjusting a feedback response of the keys of a keyboard are desirable.

### SUMMARY

This disclosure describes various embodiments that relate to mechanisms for adjusting a feedback response of keys on a keyboard.

A keyboard is disclosed and includes the following: a plurality of key assemblies, each key assembly of the plurality of key assemblies comprising: a keycap; a key stem supporting the keycap and the key stem comprising a protrusion extending laterally therefrom; a first biasing member supporting the key stem and being configured to provide a linear feedback response during actuation of the key assembly; and a second biasing member configured to engage the protrusion during actuation of the key assembly, wherein engagement of the second biasing member with the protrusion of the key assembly provides a feedback response that is user-configurable.

A keyboard is disclosed and includes the following: a plurality of key assemblies, each of the key assemblies comprising: a keycap; a key stem supporting the keycap and comprising a protrusion extending radially therefrom; a first biasing member supporting the key stem and being configured to provide a first feedback response during actuation of the key assembly; and a second biasing member configured to engage the protrusion and to provide a second feedback response different from the first feedback response when the protrusion engages the second biasing member; and a slider switch configured to reposition a portion of the second biasing member that is configured to engage the protrusion of the key stem.

A key assembly is disclosed and includes the following: a key stem comprising a protrusion extending laterally therefrom; a first biasing member supporting the key stem and being configured to provide a first feedback response during actuation of the key assembly; and a second biasing member configured to engage the protrusion during actuation of the key assembly to provide one of three or more different user-configurable feedback responses.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

The disclosure will be readily understood by the following detailed description in conjunction with the accompanying drawings, wherein like reference numerals designate like structural elements, and in which:

FIGS. 1A-1B show exemplary keyboard designs suitable for use with the described embodiments;

FIG. 2A shows an exploded perspective view of a key assembly and a feedback mechanism;

FIG. 2B shows a perspective view of a key stem configured with three different protrusions radially offset by about 90 degrees;

FIG. 2C shows a top view of a key stem having four different protrusions separated by 90 degree intervals;

FIG. 2D shows a top view of a key stem having eight different protrusions;

FIGS. 2E-2H show exemplary protrusion suitable for incorporation upon any of the key stem bodies depicted in FIGS. 2A-2D;

FIG. 3A shows a perspective cross-sectional view of a key assembly with a vertical slider switch;

FIG. 3B shows a perspective view of select components of the key assembly depicted in FIG. 3A;

FIGS. 3C-3E shows how a distance between a protrusion of a key stem and a torsion spring leg changes as a function of a position of the vertical slider switch;

FIG. 4A shows a perspective view of another key assembly;

FIG. 4B shows a perspective view of select components of the key assembly depicted in FIG. 4A; and

FIGS. 4C-4F depict how shifting a position of a leg of a torsion spring laterally can effect a position at which the leg is initially contacted by a protrusion of a key stem.

### DETAILED DESCRIPTION OF THE INVENTION

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

High-end keyboarding devices are desirable for their mechanical feedback response, which is generally deemed to provide a more positive confirmation of actuation of a particular key than would be provided by a mere dome-switch or scissor-switch mechanism. Depending on a user's preferences, physiology and the type of application being used by the user, the user may desire a particular combination of feedback response characteristics such as actuation distance, total travel distance, feedback resistance and rate of change of feedback resistance. Users desiring a particular mechanical feedback response may gravitate toward a keyboard or keyboard brand known to have a particular combination of these feedback response characteristics. Given the large population of users and variety of application types usable with a keyboard, no one feedback response may satisfy a large population of users. Furthermore, equipping each key with its own adjustment mechanism allows different keys to have different response profiles. This can be beneficial in some gaming application where, for example, it may be desirable to have a movement key with a first feedback response profile and an action key with a second feedback response profile different than the first feedback response profile.

One solution to this issue is to configure a keyboard with a user-adjustable feedback response. In some embodiments, the feedback response system can include two biasing members that cooperatively provide a feedback response profile to a user of the keyboard. The response can be tuned by a user by adjusting the key assemblies of the keyboard so that an amount of resistance provided by one or both of the biasing members changes. In some embodiments, the biasing members can take the form of a compression spring and a torsional spring. The following detailed description provides many examples of how a response of the torsional spring can be adjusted but it should be appreciated that feedback of the compression spring can also be adjusted. Furthermore, the user-adjustable feedback response could be driven by other combinations of feedback mechanisms. For example, a feedback mechanism could incorporate any one of the following biasing members: a spring mechanism, a dome switch, a foam block or an elastomeric block. These feedback mechanisms can be configured to provide three or more different user-configurable feedback response profiles. For example, the feedback mechanism can be configured to provide linear, clicky and tactile feedback response profiles.

In some embodiments, each of the key assemblies can include a rotatable key stem that includes multiple protrusions that extend radial or laterally from the rotatable key stem. Each of the protrusions can have different shapes, sizes or positions on the key stem. Rotation of the key stem results in different ones of the protrusions engaging a spring mechanism along the lines of a torsional spring as the key is being actuated. In this way, rotation of the stem changes the feedback responses. For example, a first one of the protrusions could be positioned higher up on the rotatable key stem than a second one of the protrusions. This type of configuration, with varied vertical positions of the protrusions, allows for differences in an amount of key travel prior to a second one of the spring mechanisms being engaged.

In some embodiments, each of the keys assemblies can include a switch mechanism configured to reposition one leg of a torsion spring. The key can also include a key stem that has at least one protrusion configured to engage the leg of the torsion spring during actuation of the key assembly. In some embodiments, the switch mechanism can take the form of a vertical or horizontal slider that moves the leg of the torsion spring either vertically or horizontally with respect to a direction of actuation of the key stem. In some embodiments, the slider could be configured to maneuver the end of the torsion spring both horizontally and vertically.

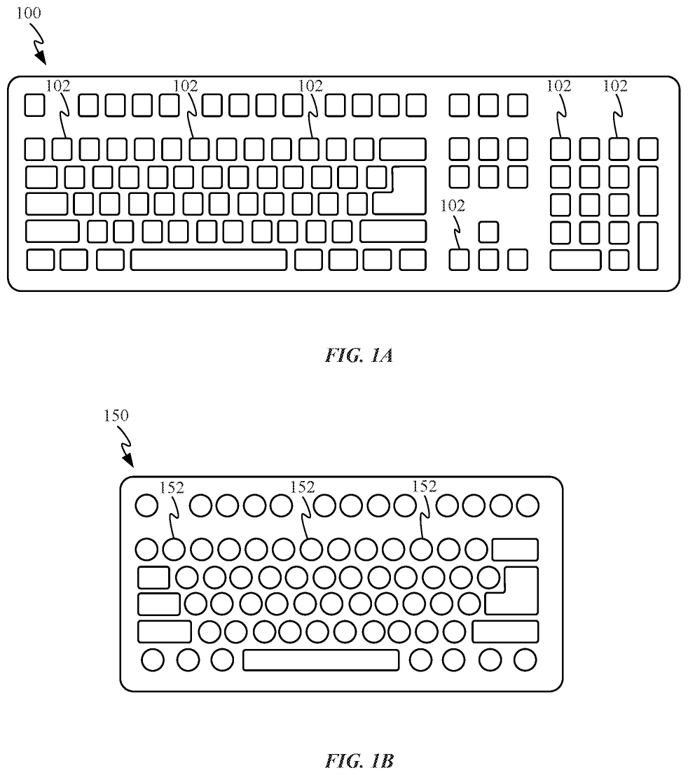

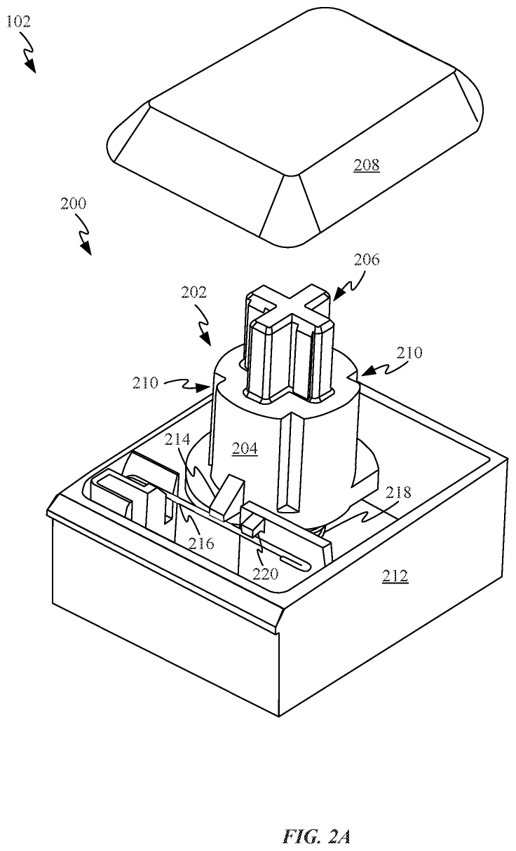

These and other embodiments are discussed below with reference to FIGS. 1A-4F; however, those skilled in the art will readily appreciate that the detailed description given herein with respect to these figures is for explanatory purposes only and should not be construed as limiting.

FIGS. 1A-1B shows exemplary keyboard designs suitable for use with the described embodiments. FIG. 1A shows keyboard 100 having multiple key assemblies 102 configured to allow a user to input commands into a computing system. Each of key assemblies 102 can include a mechanism for altering its feedback response. The mechanism can be covered by a rectangular key cap that covers the mechanism and provides a comfortable surface configured to receive an actuation force from a user's finger. When the key caps have a square geometry, key assemblies 102 can be rotated into four different orientations to facilitate changes to the feedback response of each key assembly 102. In some embodiments, keyboard 100 can include a wireless transceiver for transferring the input commands into the computing system.

FIG. 1B shows exemplary keyboard 150 with key assemblies 152. Key assemblies 152 include keycaps having a circular geometry that allows for rotation of key assemblies 152 and its associated key cap to nearly any angle. In this way, when a feedback response is adjusted by rotation of the key assembly, the circular keycap configuration increases the potential number of variations possible for changes in feedback response of key assemblies 152 without having to remove the circular keycap from key assembly 152. It should be noted that while keyboards 100 and 150 represent standalone keyboards with and without numeric pads that these keyboards could also be incorporated into a portable electronic device such as a laptop computer or even with a detachable tablet device.

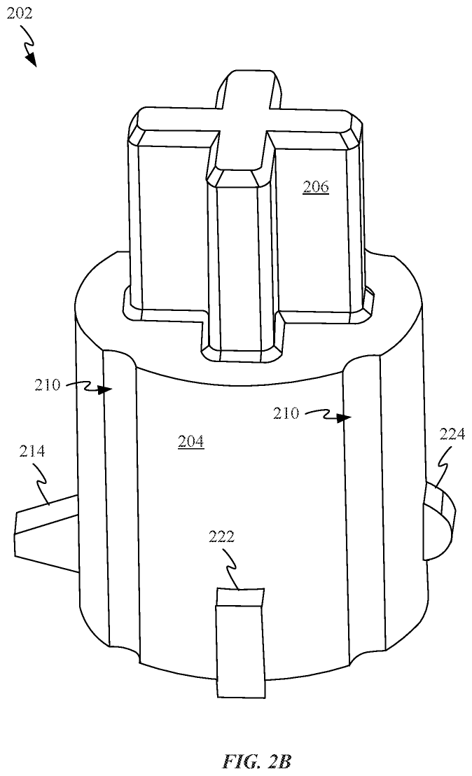

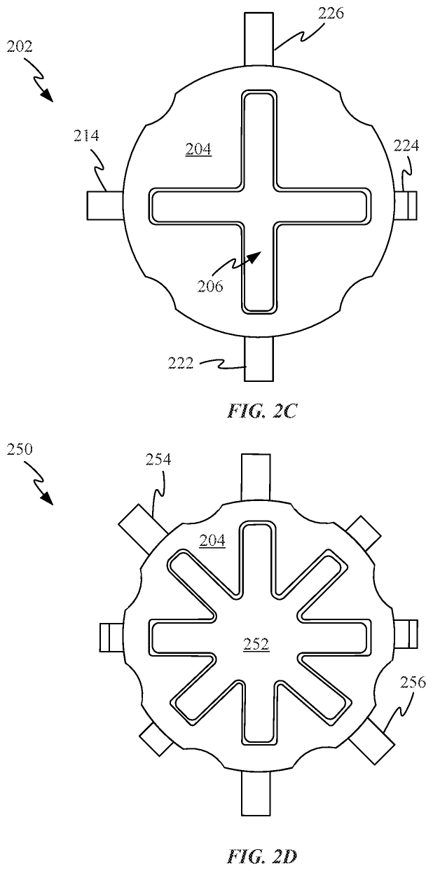

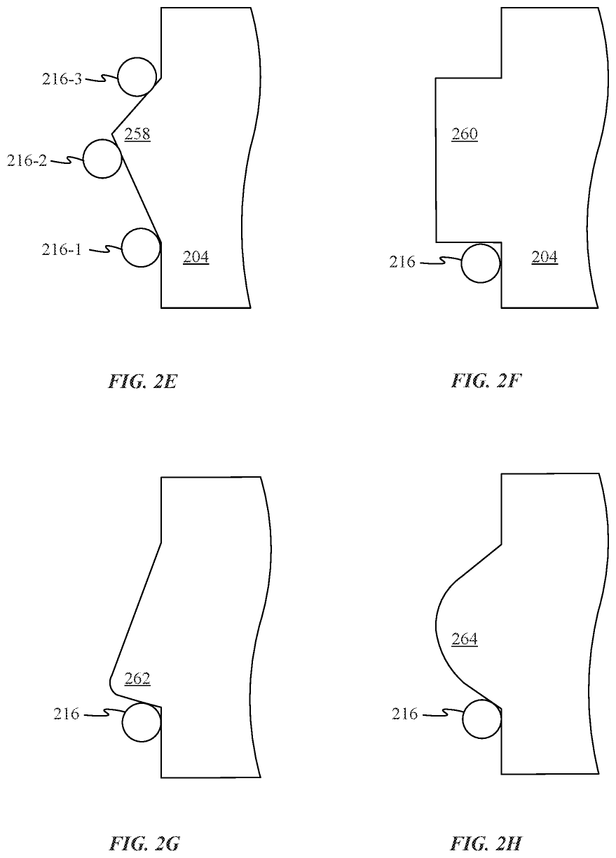

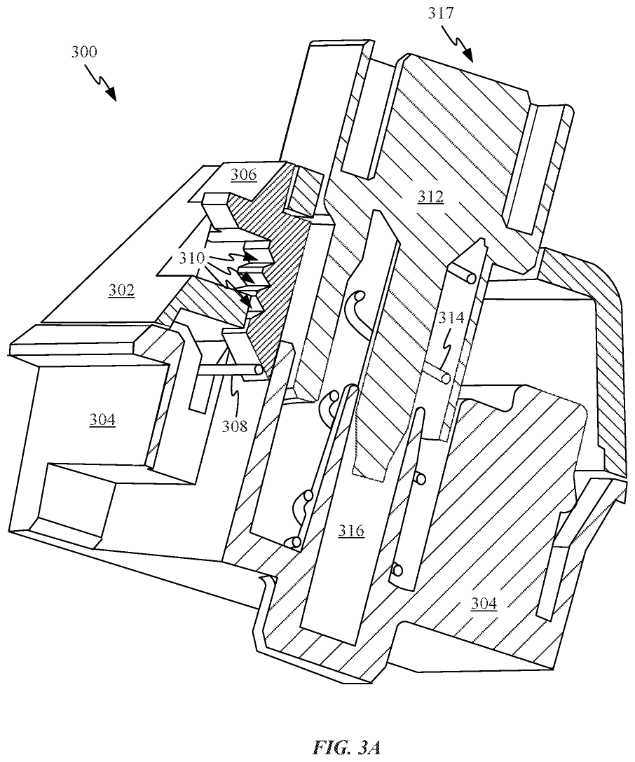

FIG. 2A shows an exploded perspective view of key assembly 102 that includes a feedback mechanism 200. Feedback mechanism 200 includes key stem 202 having a key stem body 204 with a substantially cylindrical geometry. A keycap attachment feature 206 protrudes axially from one end of key stem body 204. Keycap attachment feature 206 has a cross-shaped geometry as depicted that is configured to engage a complementary cross-shaped recess in keycap 208. Interaction between keycap attachment feature 206 and the recess in keycap 208 prevents rotation of keycap 208 relative to key stem 202. While a cross-shaped geometry of keycap attachment feature 206 is depicted it should be appreciated that keycap attachment feature 206 could have any non-circular geometry capable of preventing rotation of keycap 208. Furthermore, in some embodiments, keycap attachment feature 206 could also be engaged by a tool configured to assist a user with adjusting a feedback response of key assembly 102. A lateral exterior surface of key stem body 204 defines multiple channels 210 that are aligned with a longitudinal axis of key stem body 204. Channels 210 are configured to be engaged by one or more detents that engages channels 210 to create discrete rotational positions for key stem 202 relative to a housing component 212. These discrete positions help to align radial protrusion 214 with torsional spring 216 when key stem 202 is in a first position.

FIG. 2A also shows how torsional spring 216 is held in position relative to key stem 202 by a recess defined by housing component 212. Key stem 202 is supported within housing component 212 by a helical compression spring 218. Helical compression spring 218 can be configured to provide a linear feedback response to a user through key stem 202 and keycap 208. However, once protrusion 214 engages torsion spring 216 a resistance encountered by a user input increases. In some embodiments, the leg of torsion spring 216 engaged with protrusion 214 can slide around protrusion 214 and become disengaged from protrusion 214 providing a reduction in resistance, resulting in a user receiving a tactile indication that the user input has been received. In other embodiments, protrusion can remain engaged with protrusion 214 until an electrical contact or other electrical signal device is tripped. Housing component 212 also includes a spring stop 220 that preloads torsion spring 216. In this way, an initial amount of force imparted by torsional spring 216 can be stronger than it would otherwise be if torsion spring 216 were not being preloaded by spring stop 220. While not specifically depicted in FIG. 2A it should be appreciated that a second undepicted leg of torsion spring 216 can engage an interior-facing surface of a wall of housing component 212.

FIG. 2B shows a perspective view of key stem 202 configured with three different protrusions 214, 222 and 224 radially offset by about 90 degrees. Channels 210 are shown interspersed between each of protrusions 214, 222 and 224. Channels 210 extend from a first end of key stem body 204 to a second end of key stem body 204 opposite the first end. The generous length of channels 210 allows a detent engaging one or more of channels 210 to remain engaged during axial movement of key stem body 204. It should be noted that protrusions 214, 222 and 224 all have different shapes and sizes. Interaction between the different shapes and sizes of the various protrusions changes the feedback response provided by torsional spring 216. For example, protrusion 224 is positioned higher up on key stem body 204 than protrusions 214 and 222. For this reason, a user actuating key assembly 102 is able to press the keycap farther down before encountering a larger force provided by the torsional spring. Furthermore, the curved shape of protrusion 224 also effects the overall feel of the feedback response. In particular, protrusion 224 provides a tactile feedback response, protrusion 222 provides an additional linear feedback response and protrusion 214 provides a more defined click feedback response to a user input.

FIG. 2C shows a top view of key stem 202 having four different protrusions separated by 90-degree intervals. In particular, FIG. 2C shows how protrusion 226 can extend substantially farther from key stem body 204 than protrusions 214, 222 and 224. A longer protrusion has the advantage of reducing the likelihood of a leg of the torsional spring slipping around the protrusion when a linear response is desired from the torsional spring. FIG. 2D shows a top view of key stem 250 eight different protrusions and that is also compatible with key assembly 102. In particular, key stem 250 illustrates a keycap attachment feature 252 with a different shape than the keycap attachment feature of key stem 202. In particular, key stem 250 is configured to accommodate eight different rotational positions of key stem 250 with respect to a housing component of a key assembly. Key stem 250 also includes eight protrusions to match the eight positions. In some embodiments, protrusions on opposing sides of key stem body 204 can have the same size and shape. In such a configuration, protrusions 228 and 230 can be configured to engage torsions springs positioned on opposing sides of key stem 250. This could be desirable as engaging springs on two sides of key stem body 204 keeps the feedback response from the torsion springs symmetric.

FIGS. 2E-2H show exemplary protrusion 258-264 suitable for incorporation upon key stem body 204. FIG. 2E shows a cross-sectional side view of protrusion 258, which has a gradual ramp profile of less than 45 degrees, which allows only a small portion of the force exerted by torsion spring 216 to be applied to key stem body 204. Even though protrusion 258 has a linear slope, an amount of force applied by torsion spring 216 would tend to increase as a leg of torsion spring 216 reaches the position indicated by label 216-2 due to the resistance to lateral deflection of the leg increases. When torsion spring 216 reaches position 216-3, the total feedback response returns to being governed solely by a compression spring supporting key stem body 204. FIG. 2F shows a cross-sectional side view of protrusion 260. Protrusion 260 has a flat downward-facing surface oriented toward torsion spring 216. This flat face does not encourage lateral movement of torsion spring 216. In some embodiments, the downward-facing surface of protrusion 260 can be slanted toward a lateral-facing surface of key stem body 204, thereby further discouraging torsion spring 216 from sliding around protrusion 260. In this way, protrusion 260 is able to provide a linear feedback response when engaging a leg of torsion spring 216.

FIG. 2G shows a cross-sectional side view of protrusion 262 having a pronounced slope greater than 45 degrees that allows almost as much force to be transferred to key stem body 204 as protrusion 260. However, the sloped surface contacting torsion spring 216 allows torsion spring 216 to slide around protrusion 262. This results in a user receiving a pronounced click feedback that clearly communicates successful actuation of an associated key assembly. FIG. 2H shows a protrusion 264 having a convex geometry that on first contact with torsion spring 216 provides a firm increase in force and then as torsion spring shifts laterally the force provided by torsion spring 216 gradually tapers off until the leg of torsion spring 216 passes protrusion 264.

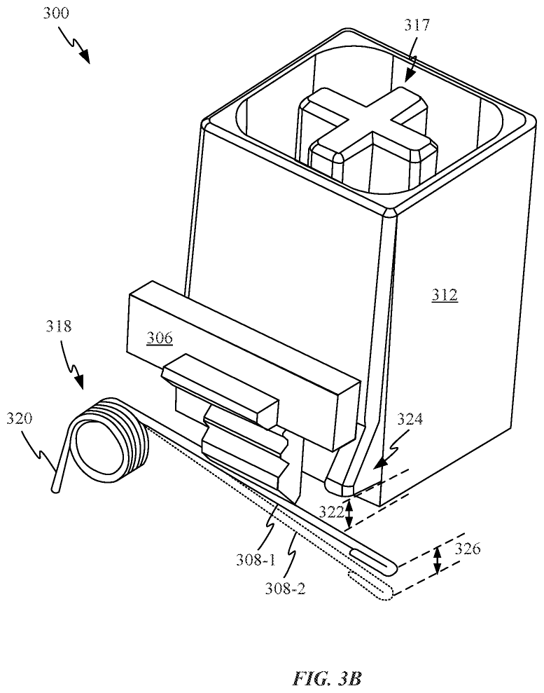

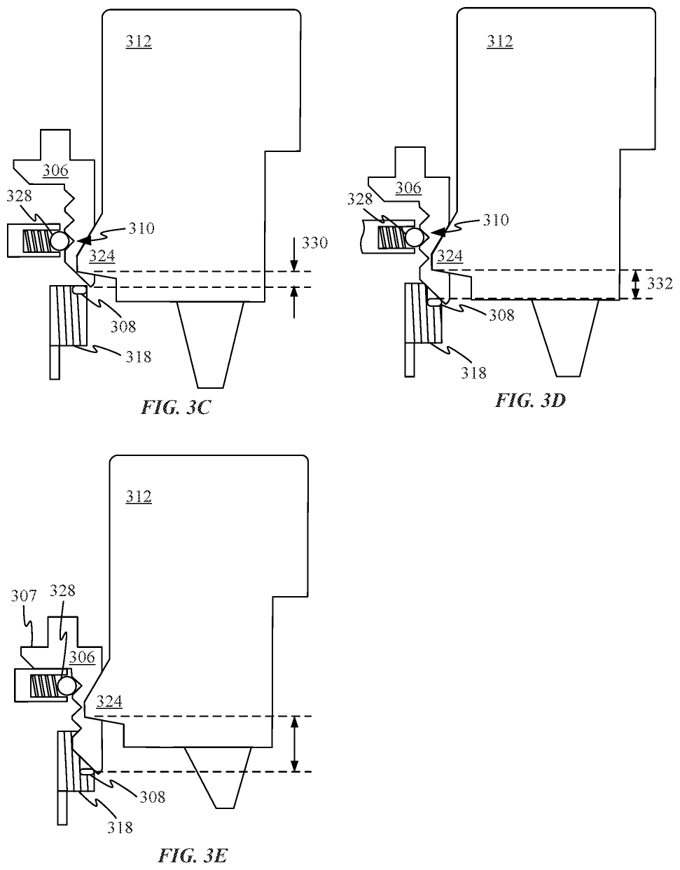

FIG. 3A shows a perspective cross-sectional view of a key assembly 300. Key assembly 300 includes a housing made up of upper housing component 302 and lower housing component 304. Upper housing component 302 defines a channel that accommodates a slider switch 306. A position of slider switch 306 can be changed by a user in order to adjust a starting position of a leg 308 of a torsion spring. A face of slider switch 306 that contacts leg 308 of the torsion spring can be slanted, which can result in both vertical and horizontal motion of leg 308 depending upon a position of slider switch 306. Slider switch 306 can be held in place by a spring loaded detent, incorporated within upper housing component 302, that is configured to engage one of channels 310 defined by slider switch 306. In this way, a user is able to shift a position of leg 308 by maneuvering slider switch 306 up or down relative to upper housing component 302. In this way, an engagement point for leg 308 can be shifted by between one and five millimeters.

FIG. 3A also shows how key stem 312 is supported above a base of wall of lower housing component 304 by compression spring 314. Key stem 312 includes a protruding central region configured to engage a channel 316 defined by lower housing component. Interaction between the protruding central region and walls defining channel 316 help to prevent any wobble of key stem 312 during actuation of key assembly 300. While a keycap is not depicted in FIG. 3A it should be appreciated that a keycap can engage keycap attachment feature 317 in order to provide a smooth surface for a user to rest a finger upon key assembly 300.

FIG. 3B shows a perspective view of select components of key assembly 300. In particular, an entirety of slider switch 306 and torsion spring 318 are depicted. Torsion spring 318 includes legs 308 and 320. Torsion spring does not begin providing a feedback response until key stem 312 traverses a distance 322 and protrusion 324 engages leg 308 of torsion spring 318. As protrusion 324 continues to move downward across distance 326, a position of leg 308 moves from position 308-1 to position 308-2. Slider switch 306 is shown including a user-accessible tab 307 for making manipulation of slider switch 306 easier.

FIGS. 3C-3E shows how a distance between protrusion 324 and leg 308 of torsion spring 318 changes as a function of a position of slider switch 306. FIG. 3C shows spring-loaded detent 328 engaged with a first channel 310 of slider switch 306. In this position, slider switch 306 either has no contact with leg 308 at all or merely keep leg 308 in a horizontal position resulting in a distance 330 between protrusion 324 and leg 308 being minimized. FIG. 3D shows detent 328 engaging a second one of channels 310. In this configuration, a more noticeable delay is established between initially actuating key assembly 300 and receiving a feedback response from torsion spring 318 that augments the feedback response from compression spring 314 (see FIG. 3A).

FIG. 3E shows detent 328 engaging a third one of channels 310. In this configuration, leg 308 can be displaced far enough down to avoid any contact between protrusion 324 and leg 308. In other embodiments, the third one of the channels can still result in a modicum of contact between protrusion 324 and leg 308. It should be noted that while slider switch is depicted including only three channels 310, that a larger or smaller amount of channels 310 is also possible. For example, two, four, five or more channels 310 are possible. In some embodiments, this would allow for leg 308 to be moved farther away from protrusion 324, while in other embodiments, channels 310 could have a smaller size allowing for an exact position of slider switch to be fine-tuned to a desired position. In some embodiments and as depicted in FIG. 3E, a portion of lower housing component 304 that defines a channel for spring-loaded detent 328 can also act as a stop to prevent slider switch from pushing too hard upon leg 308 of torsion spring 318.

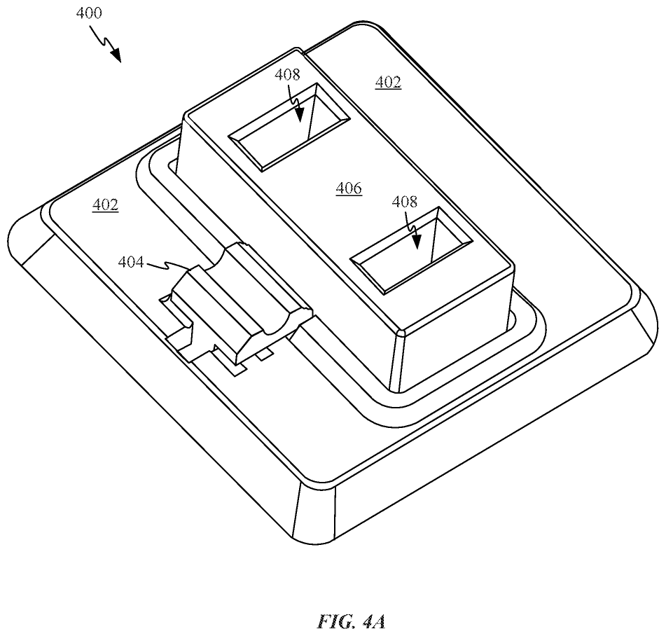

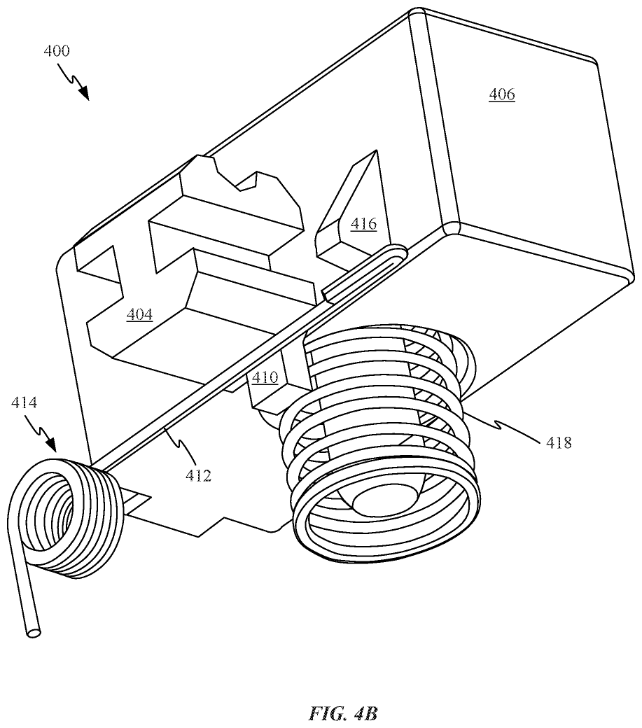

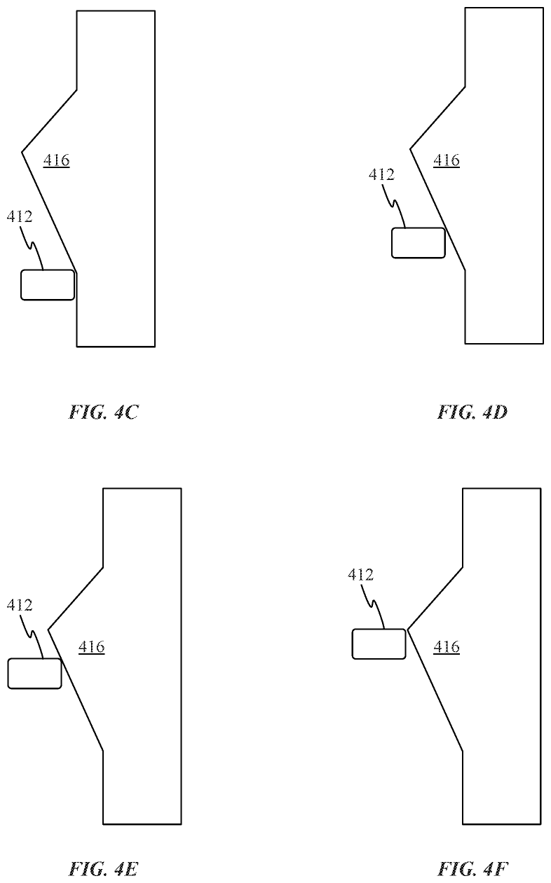

FIG. 4A shows a perspective view of a key assembly 400. Key assembly 300 includes housing component 402. Housing component 402 defines a channel that accommodates slider switch 404. A position of slider switch 404 can be changed by a user in order to adjust a starting position of a leg of a torsion spring within housing component 402. FIG. 4A also depicts key stem 406, which defines two prong openings 408 that can be engaged by prongs protruding from a keycap (not depicted). Key stem 406 can be supported by a compression spring that returns key stem 406 to its depicted position after a user releases pressure on key assembly 400.

FIG. 4B shows a perspective view of select components of key assembly 400. In particular, a shape of a lower portion of slider switch 404 is depicted. Slider switch 404 has an I-shaped cross-sectional geometry that allows it to engage both upward and downward faces of housing component 402 (see FIG. 4A) to prevent it from becoming dislodged from housing component 402. Slider switch 404 includes a hooking mechanism 410 configured to shift a leg 412 of torsion spring 414 away from key stem 406 in response to movement of slider switch 404. In some embodiments, slider switch 404 can move leg 412 far enough away to prevent any contact between leg 412 and protrusion. By placing leg 412 in this manner a force response of key assembly 400 could be limited to a linear force response provided by compression spring 418. However, it should be noted that slider switch 404 can include intermediate positions in which leg 412 is shifted only enough to delay or reduce engagement with protrusion 416, which extends laterally from a face of key stem 406.

FIGS. 4C-4F depict how shifting leg 412 of torsion spring 414 laterally can effect a position at which leg 412 initially contacts protrusion 416. In particular, FIG. 4C shows how when slider switch is as positioned as close as possible to key stem 406, leg 412 contacts a base of protrusion 416 allowing leg 412 to trace entirely around protrusion 416 during actuation of key assembly 400. FIGS. 4D-4E depict intermediate positions of slider switch 404 and indicate how a duration of a feedback response provided by protrusion 416 can be ameliorated. FIG. 4F shows how in its position furthest from key stem 406 leg 412 can completely bypass contact with protrusion 416. While only four variations are shown here it should be appreciated that a number of positions of slider switch 404 can vary greatly from as few as two positions to a slider providing an infinite number of positions enabled by slider switch 404 being only coupled to housing component 402 by a friction coupling that allows its position to be fine-tuned. Furthermore, the embodiments, from FIG. 4A-4F can be combined with the teachings from FIGS. 3A-3E. For example, slider switch 404 could be equipped with a plunger switch capable of shifting leg 412 downward, allowing for a delayed engagement between leg 412 and protrusion 416. This configuration could advantageously allow an increased amount of feedback customization as both horizontal and vertical positioning of a leg of torsional spring 414 can be fine-tuned.

It should be appreciated that in some embodiments, additional customization could be achieved by combining a rotatable key stem having multiple protrusions with a slider switch configured to adjust the position of a leg of a torsion spring. Other combinations of features are also possible and deemed to be within the scope of the disclosure.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A keyboard, comprising:
a plurality of key assemblies, each key assembly of the plurality of key assemblies comprising:
a keycap;
a key stem supporting the keycap and the key stem comprising a protrusion extending laterally therefrom;
a first biasing member supporting the key stem and being configured to provide a linear feedback response during actuation of the key assembly; and
a second biasing member configured to engage the protrusion during actuation of the key assembly, wherein engagement of the second biasing member with the protrusion of the key assembly provides a feedback response that is user-configurable.

2. The keyboard as recited in claim 1, wherein each of the key assemblies further comprises a slider switch configured to reposition a portion of the second biasing member that is configured to engage the protrusion of the key stem.

3. The keyboard as recited in claim 2, wherein the slider switch is configured to reposition the portion of the second biasing member so that the second biasing member does not engage the protrusion.

4. The keyboard as recited in claim 1, wherein the first and second biasing members both comprise spring members.

5. The keyboard as recited in claim 1, wherein the first biasing member is a compression spring and the second biasing member is a torsional spring.

6. The keyboard as recited in claim 1, wherein the key stem is a rotatable key stem and the protrusion is a first protrusion and wherein the keyboard further comprises second and third protrusions extending laterally from the key stem.

7. The keyboard as recited in claim 6, wherein the first protrusion has a different shape than the second protrusion.

8. The keyboard as recited in claim 6, wherein when the rotatable key stem is in a first position the first protrusion is aligned with and positioned to engage the second biasing member and when the rotatable key stem is in a second position the second protrusion is aligned with and positioned to engage the second biasing member.

9. The keyboard as recited in claim 8, wherein the first protrusion is positioned closer to the keycap than the second protrusion.

10. The keyboard as recited in claim 8, wherein when the key stem is in a third position the third protrusion is aligned with and positioned to engage the second biasing member.

11. The keyboard as recited in claim 8, wherein rotation of the key stem from a first position to a second position changes the user-configurable feedback response provided by engagement of the second biasing member by the second protrusion.

12. A keyboard, comprising:
a plurality of key assemblies, each of the key assemblies comprising:
a keycap;
a key stem supporting the keycap and comprising a protrusion extending radially therefrom;
a first biasing member supporting the key stem and being configured to provide a first feedback response during actuation of the key assembly; and
a second biasing member configured to engage the protrusion and to provide a second feedback response different from the first feedback response when the protrusion engages the second biasing member; and
a slider switch configured to reposition a portion of the second biasing member that is configured to engage the protrusion of the key stem.

13. The keyboard as recited in claim 12, wherein the first feedback response is a linear feedback response and the second feedback response is a non-linear feedback response.

14. The keyboard as recited in claim 12, wherein the first biasing member is a compression spring and the second biasing member is a torsion spring.

15. The keyboard as recited in claim 14, wherein the protrusion of the key stem is configured to engage a first leg of the torsion spring.

16. The keyboard as recited in claim 14, wherein the portion of the torsion spring configured to engage the protrusion is a distal end of a first leg of the torsion spring and the slider switch is configured to engage a central portion of the first leg of the torsion spring to reposition the distal end of the second biasing member.

17. A key assembly, comprising:
a key stem comprising a protrusion extending laterally therefrom;
a first biasing member supporting the key stem and being configured to provide a first feedback response during actuation of the key assembly; and
a second biasing member configured to engage the protrusion during actuation of the key assembly to provide one of three or more different user-configurable feedback responses.

18. The key assembly as recited in claim 17, wherein the key stem is a rotatable key stem comprising a plurality of protrusion.

19. The key assembly as recited in claim 18, wherein each of the plurality of protrusions corresponds to a respective one of the three or more different user-configurable feedback responses.

20. The key assembly as recited in claim 17, wherein the second biasing member comprises a torsion spring and the key assembly further comprises a slider switch configured to shift a position of a leg of the torsion spring to change the feedback response from a first one of the three or more different user-configurable feedback responses to a second one of the three or more different user-configurable feedback responses.
